(19) United States
(12) Patent Application Publication
(10) Pub. No.: US 2009/0231325 A1
(43) Pub. Date: Sep. 17, 2009

(54) Display device

(75) Inventors: Ryouhei Suzuki, Mobara (JP); Kenji Kitajima, Ooamishirasato (JP)

Correspondence Address: Juan Carlos A. Marquez;c/o Stites & Harbison PLLC, 1199 North Fairfax Street, Suite 900, Alexandria, VA, 22314-1437, US

(73) Assignee: Hitachi Displays, Ltd.

(21) Appl. No.: 12/292,507

(22) Filed: Nov. 20, 2008

(30) Foreign Application Priority Data
Mar. 13, 2008 (JP) 2008-064213

(51) Int. Cl. G06F 3/038; G09G 3/20

(52) U.S. Cl. 345/214; 345/55

(57) ABSTRACT

In a display device having a video signal drive circuit disposed laterally adjacent to the screen, the frame area is reduced and the vertical line noise at the center of the screen is prevented from appearing. Driver lines are drawn to areas disposed above and below a display area from the video signal drive circuit. R, G, and B drain lines are branched from each of the driver lines via R, G, and B switches. The R, G, and B switches are driven by R, G, and B switching lines. In order for preventing the interference between the driver line for supplying the center area of the screen with the image signals and the B switching line, a shield line is disposed between the driver line and the B switching line.

The present application claims priority from Japanese application JP2008-64213 filed on Mar. 13, 2008, the content of which is hereby incorporated by reference into this application.

### BACKGROUND OF THE INVENTION

The present invention relates to a display device, and in particular to a small-sized flat-panel display device having a large display area with respect to the overall size.

Since liquid crystal displays and organic EL displays are flat and lightweight, usage thereof has been spreading in a variety of fields. For mobile phones and digital still cameras (DSC), small-sized liquid crystal displays, organic EL displays, and so on are used widely. In these display devices, the overall size is required to be as small as possible. On the other hand, the larger display areas are more eye-friendly. Therefore, there are required display devices having a large display area while having a small overall size.

In the circumferential area of a display device, there exist outgoing lines of video signal lines (drain lines) for transmitting video signals to pixels, outgoing lines of scan lines, and so on. Further, in most cases, clock signal lines or the like for controlling video data are also disposed. When increasing the display area and decreasing the overall size, the space for accommodating the drain lines, the scan lines, the clock lines, and so on disposed around the display area is reduced, and therefore, the distances between these lines are also reduced.

If the distance between these signal lines is reduced, capacitance between the lines increases to cause interference between the lines. In JP-A-11-202367 and JP-A-11-223832, there is described a configuration of disposing a shield line between these lines to prevent the interference between the clock signal line and the drain line.

### SUMMARY OF THE INVENTION

When increasing the display area while keeping the small overall size, a so-called frame area becomes smaller. Since the video signal lines for supplying the pixels with the video signals are disposed in the frame area, if the frame area is reduced, a space for disposing the outgoing lines of the video signal lines, and so on becomes insufficient.

As a measure against this problem, there exists a technology of combining three outgoing lines of the drain lines for supplying the RGB video signals forming a set of pixels into a single driver line, and disposing a dividing switch immediately before the display area to supply the sub-pixels of RGB with the respective video signals by operations of the dividing switch. The dividing switch is typically formed of a thin film transistor (TFT), and the same number of dividing switches as the number of drain lines are disposed at the entrances of the respective drain lines.

In this configuration, the number of the driver lines becomes a third of the number of the drain lines required in the display area. Since the driver lines exist in the frame area, the number of signal lines becomes a third of that of the related art, and even if the area of the frame is reduced, the necessary wiring can be achieved. However, in the case with this configuration, there are required RGB switching lines for operating the dividing switches.

In the mobile phones or the like, a video signal drive circuit is disposed on the down side of the display area. However, in DSCs or the like, due to the form of use, the video signal drive circuit needs to be disposed in an area laterally adjacent to the display area. In this case, the driver lines and the RGB switching lines are sometimes disposed in parallel to each other for a long distance. In such a case, there arises a problem of interference between the RGB switching lines and the driver lines.

FIG. 7 is an equivalent circuit showing the problem described above. FIG. 7 shows the wiring of a liquid crystal display panel. In FIG. 7, the display area 500 is provided with a number of pixels formed in a matrix. Each of the pixels is composed of sub-pixels executing display with RGB. Each of the sub-pixels is provided with a TFT used as a switch.

On the left of the display area 500, there is disposed a scan signal drive circuit 400. From the scan signal drive circuit 400, scan lines 20 extend to the display area 500. The number of the scan lines 20 corresponds to the number of the pixels aligned in a vertical line of the display area 500. On the right of the display area 500, there is disposed a video signal drive circuit 300. From the video signal drive circuit 300, driver lines 10 extend to the areas above and below the display area 500, respectively. The pixels located on the left half of the display area 500 are supplied with the video signals by the driver lines 10 passing through the area above the display area 500, and the pixels located on the right half of the display area 500 are supplied with the video signals by the driver signal 10 passing through the area below the display area 500.

Further, from the video signal drive circuit 300, the RGB switching lines 30, 40, and 50 for the RGB dividing switches extend to the areas above and below the display area 500 similarly to the driver lines 10. Three of the RGB switching lines 30, 40, and 50 extend upward respectively for RGB, and also three thereof extend downward respectively for RGB.

In FIG. 7, the RGB switching lines 30, 40, and 50 are disposed outside the driver lines 10 in the both areas above and below the display area 500. In the three RGB switching lines 30, 40, and 50, the B switching line 30 is disposed on the inner most side, then the G switching line 40 is disposed, and the R switching line 50 is disposed on the outermost side in the both areas above and below the display area 500. Therefore, there arises the problem of interference between the B switching line 30 and the outermost driver line 10.

In FIG. 7, the interference between the B switching line 30 and the driver line D1 adjacent thereto causes a problem in the area above the display area 500, and in the area below the display area 500, the B switching line 30 and the driver line D3 adjacent thereto causes a problem. FIG. 8 shows a cross-sectional view illustrating the condition of the interference.

In FIG. 8, the driver line 10 (the driver line D1) and the RGB switching lines 30, 40, and 50 (including the B switching line 30) are also formed in the same layer as the drain lines 11, and all of them are formed on an interlayer insulating film 106. The driver lines 10 and the RGB switching lines (the R switching lines 50, the G switching lines 40, and the B switching lines 30) are covered by an inorganic passivation film 109 and a planarizing film 110 as an organic passivation film.

Since the inorganic passivation film 109 and the planarizing film 110 both have a large dielectric constant, and therefore, form a line capacitance therebetween. Therefore, the signals on the both lines should interfere with each other. In the particularly problematical interference, the switching signal on the B switching line 30 has an influence on the driver line 10.

Going back to FIG. 7, the interference between the B switching line 30 and the driver line 10 in the area above the display area 500 has an influence only on the left end area of the display area 500. The modulation of the image in the end areas of the display area 500 is not very noticeable, and therefore, is not a big problem. In contrast, the interference between the B switching line 30 and the driver line 10 has an influence on the center part of the display area 500, and therefore, causes a big problem.

The present invention is for providing a measure against the problem caused by the interference between the driver lines 10 and the RGB switching lines in the case in which the video signal drive circuit 300 locates in an area laterally adjacent to the display area 500 to provide the driver lines 10 to the areas both above and below the display area 500.

The present invention is for solving the problems described above, and has specific measures as follows.

(1) A display device includes a display area divided into a first display section and a second display section, a video signal drive circuit disposed laterally adjacent to the display area and closer to the first display section than to the second display section, at least two driver lines connected to the video signal drive circuit and adapted to supply the first display section with a plurality of video signals via one of areas above and below the display area, and to supply the second display section with a plurality of video signals via the other of the areas above and below the display area, an R drain line branched from each of the driver lines via an R switch and adapted to supply red sub-pixels in the display area with one of the video signals, a G drain line branched from each of the driver lines via a G switch and adapted to supply green sub-pixels in the display area with another of the video signals, a B drain line branched from each of the driver lines via a B switch and adapted to supply blue sub-pixels in the display area with another of the video signals, an R switching line adapted to control the R switch, a G switching line adapted to control the G switch, a B switching line adapted to control the B switch, and a shield line disposed between one of the driver lines supplying the R, G, and B drain lines in a boundary section between the first and second display sections with the video signals and either one of the R, G, and B switching lines adjacent to the driver line supplying the R, G, and B drain lines in the boundary section with the video signals.

(2) In the display device according to (1), the driver line supplying the R, G, and B drain lines in the boundary section between the first and second display sections with the video signals supplies the first display section with the video signals.

(3) In the display device according to (1), the first and second display sections have the same area.

(4) In the display device according to (1), the R, G, and B switches are each formed of a TFT.

(5) In the display device according to (1), the either one of the R, G, and B switching lines adjacent to the driver line supplying the R, G, and B drain lines in the boundary section between the first and second display sections with the video signals is the B switching line.

(6) In the display device according to (1), the driver lines, the shield line, and the R, G, and B switching lines are formed in the same layer.

(7) In the display device according to (1), the shield line has a larger width than the widths of the driver lines, and the R, G, and B switching lines.

(8) A display device includes a display area, a video signal drive circuit disposed laterally adjacent to the display area, a first driver line connected to the video signal drive circuit and disposed in an area above the display area, a second driver line connected to the video signal drive circuit and disposed in an area below the display area, a first R drain line branched from the first driver line via a first R switch and adapted to supply red sub-pixels with one of the video signals, a first G drain line branched from the first driver line via a first G switch and adapted to supply green sub-pixels with another of the video signals, a first B drain line branched from the first driver line via a first B switch and adapted to supply blue sub-pixels with another of the video signals, a second R drain line branched from the second driver line via a second R switch and adapted to supply red sub-pixels with one of the video signals, a second G drain line branched from the second driver line via a second G switch and adapted to supply green sub-pixels with another of the video signals, a second B drain line branched from the second driver line via a second B switch and adapted to supply blue sub-pixels with another of the video signals, and at least one set of the first R, G, and B drain lines and at least one set of the second R, G, and B drain lines exist alternately in the display area.

(9) In the display device according to (8), an R switching line adapted to control the first and second R switches, a G switching line adapted to control the first and second G switches, a B switching line adapted to control the first and second B switches are further provided, the R, G, and B switching lines are disposed between the first driver line and the display area in the area above the display area, and between the second driver line and the display area in the area below the display area.

(10) In the display device according to (9), a shield line is further disposed between a set of the R, G, and B switching lines, and at least one of the first and second driver lines the closest to the set of the R, G, and B switching lines.

(11) In the display device according to (8), the first and second R, G, and B switches are each formed of a TFT.

(12) A display device includes a display area divided into a first display section and a second display section, a video signal drive circuit disposed laterally adjacent to the display area and closer to the first display section than to the second display section, at least two driver lines connected to the video signal drive circuit and adapted to supply the first display section with a plurality of video signals via one of areas above and below the display area, and to supply the second display section with a plurality of video signals via the other of the areas above and below the display area, an R drain line branched from each of the driver lines via an R switch and adapted to supply red sub-pixels in the display area with one of the video signals, a G drain line branched from each of the driver lines via a G switch and adapted to supply green sub-pixels in the display area with another of the video signals, a B drain line branched from each of the driver lines via a B switch and adapted to supply blue sub-pixels in the display area with another of the video signals, an R switching line adapted to control the R switch, a G switching line adapted to control the G switch, a B switching line adapted to control the B switch, and a shield line intervening between one of the driver lines supplying the R, G, and B drain lines in a boundary section between the first and second display sections with the video signals and either one of the R, G, and B switching lines adjacent to the driver line supplying the R, G, and B drain lines in the boundary section with the video signals via an insulating film so as to overlap at least one of the driver line supplying the R, G, and B drain lines in the boundary section with the video signals and the either one of the R, G, and B switching lines adjacent to the driver line supplying the R, G, and B drain lines in the boundary section with the video signals.

(13) In the display device according to (12), the shield line has a larger width than the widths of the driver lines, and the R, G, and B switching lines.

(14) In the display device according to any one of (1) through (13), the display device is a liquid crystal display.

(15) In the display device according to any one of (1) through (13), the display device is an organic EL display.

According to the present invention, since the shield is disposed between the driver line supplying the center section of the screen with the video signals and the switching line for switching the pixels, the vertical line noise in the center section of the screen can be prevented.

According to another aspect of the invention, since the video signals to the sets of the R, G, and B drain lines for supplying the sub-pixels with the video signals are supplied from the above and below the display area alternately, the interference between the driver lines and the switching lines for switching the pixels can be suppressed to a low level, and the affected area can be limited to the end area of the screen, thus the degradation of the image quality can be prevented.

### BRIEF DESCRIPTION OF THE DRAWINGS

FIG. 1 is a circuit diagram of a display device according to a first embodiment of the invention.

FIG. 2 is a cross-sectional view along the A-A′ line shown in FIG. 1.

FIG. 3 is a cross-sectional view of a liquid crystal display.

FIG. 4 is a cross-sectional view of an organic EL display.

FIG. 5 is a circuit diagram of a display device according to a second embodiment of the invention.

FIG. 6 is a cross-sectional view of a third embodiment of the invention.

FIG. 7 is a circuit diagram of a display device of a related art example.

FIG. 8 is a cross-sectional view along the A-A′ line shown in FIG. 7.

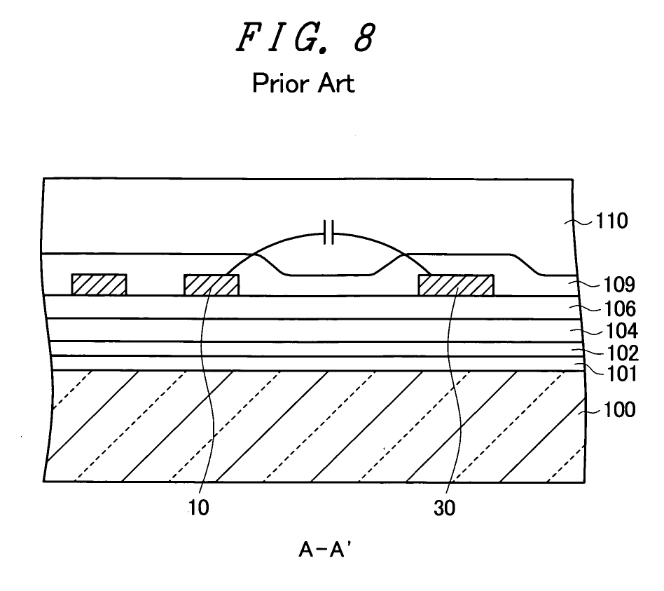

### DESCRIPTION OF THE PREFERRED EMBODIMENT

The present invention can be applied to flat-panel displays such as liquid crystal displays or organic EL displays. This is because in both display devices, the switch for each sub-pixel is formed of a TFT, and further, the RGB dividing switch can also be formed of a TFT. Further, in these display devices, a part of or the whole drive circuit is sometimes formed of TFTs.

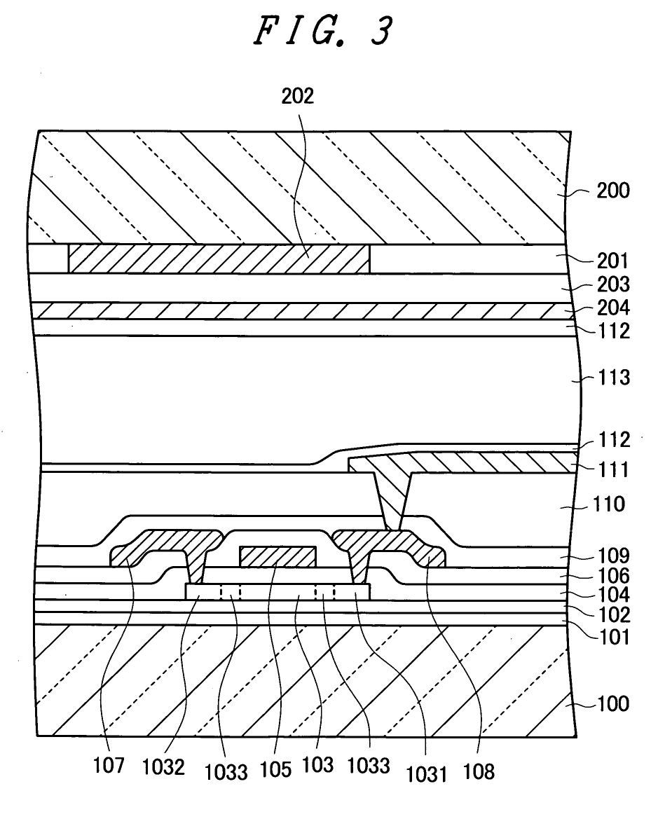

In the case in which not only the pixel switches but also the RGB dividing switches (R switches 51, G switches 41, and B switches 31) and the drive circuit are formed of TFTs, so-called low-temperature polysilicon (LTPS) TFTs are used. FIG. 3 shows a cross-sectional structure of a liquid crystal display panel using the LTPS type TFT to which the present invention is applied. In FIG. 3, the upper surface of a TFT substrate 100 is coated with a first base film 101 made of SiN, and the upper surface of the first base film 101 is coated with a second base film 102 formed, for example, of a silicon oxide film. The film thickness of the first base film 101 is 150 nm, and the film thickness of the second base film 102 is 100 nm. The purpose of both of these films is to prevent impurities from being separated out from a glass substrate as a base to contaminate a semiconductor film 103.

On the second base film 102, there is formed the semiconductor film 103. The semiconductor film 103 is obtained by converting an a-Si film into a poly-Si film with a laser annealing process. A gate insulating film 104 made of SiO2 is formed so as to cover the semiconductor film 103 with a thickness of about 300 nm, and a gate electrode 105 is formed on the gate insulating film 104. It should be noted that the semiconductor film 103 is divided into a plurality of regions. Immediately beneath the gate electrode 105, there is formed a channel region. A drain region 1032 is formed in the left end of the semiconductor film 103 shown in FIG. 3, and in the right end thereof, there is formed a source region 1031. The drain region 1032 and the source region 1031 are formed by doping impurities to the semiconductor film 103 using the gate electrode 105 as a mask. Between the source region 1031 and the drain region 1032, there is formed a lightly-doped drain (LDD) region 1033 having a dielectric constant lower than those of the source region 1031 and the drain region 1032 by lightly doping the impurities.

An interlayer insulating film 106 made of SiN is formed so as to cover the gate electrode 105 with a thickness of about 300 nm. On the interlayer insulating film 106, there are formed a drain electrode 107 and a source electrode 108. The drain electrode 107 and the source electrode 108 are formed in the same layer as the drain line 11. Further, a shield line 60, which is one of the features of the present invention, is also formed in the same layer as the drain electrode 107 and the source electrode 108. The drain electrode 107 is electrically connected to the drain line 11, and the source electrode 108 is electrically connected to the pixel electrode 111.

The interlayer insulating film 106 is provided with through-holes, through which the drain electrode 107 is electrically connected to the drain region 1032 of the semiconductor film 103, and the source electrode 108 is electrically connected to the source region 1031 of the semiconductor film 103, respectively. The upper surfaces of the source electrode 108 and the drain electrode 107 are coated with an inorganic passivation film 109 made of SiN with a thickness of about 300 nm. Further, on the inorganic passivation film 109, there is formed the planarizing film 110 made of resin. The planarizing film 110 is made typically of acrylic resin. Due to the purpose thereof, the planarizing film 110 has a relatively large thickness, and is formed to have a thickness of about 1 through 2 μm. The planarizing film 110 also has a role as an organic passivation film.

On the planarizing film 110, there is formed a pixel electrode 111. The pixel electrode 111 is electrically connected to the source electrode 108 via a through-hole provided to the inorganic passivation film 109 and the planarizing film 110. An oriented film 112 for orienting the liquid crystal is formed so as to cover the pixel electrode 111. A liquid crystal layer 113 is held between the TFT substrate 100 and a opposed substrate 200.

The opposed substrate 200 is provided with a color filter 201 and a light-shielding film 202. The light-shielding film 202 is for shielding an area not contributing to image formation with a black film, and has a role of enhancing the contrast of an image. An overcoat film 203 for planarizing the surface is formed so as to cover the color filter 201 and the light-shielding film 202, and an opposed electrode 204 is formed on the overcoat film 203. An oriented film 112 for orienting the liquid crystal is formed so as to cover the opposed electrode 204.

The liquid crystal display shown in FIG. 3 has a so-called TN liquid crystal drive mode as an example. The present invention is not limited to the TN mode, but can also be applied to liquid crystal displays adopting other modes such as an IPS mode for rotating the liquid crystal in a direction parallel to the surface of the substrate, or a VA mode having a vertical initial orienting direction of the liquid crystal.

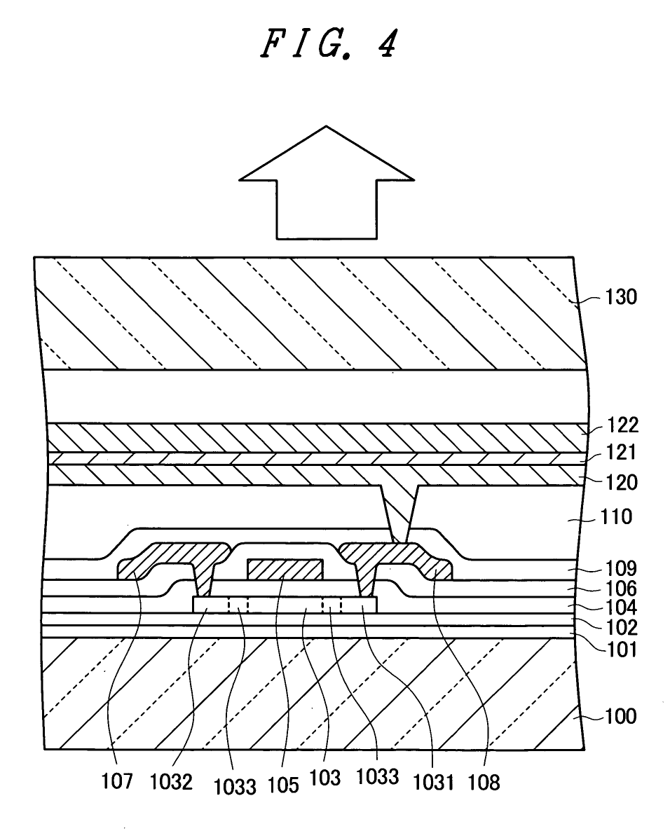

The present invention can be applied not only to the liquid crystal displays, but also to, for example, organic EL displays. FIG. 4 is a cross-sectional view of a so-called top-emission organic EL display. In FIG. 4, the LTPS type TFT is formed on the TFT substrate 100. The structure up to the inorganic passivation film 109 and the planarizing film 110 covering the TFT is the same as in the case with the liquid crystal display explained with reference to FIG. 3, and therefore, the explanation therefor will be omitted here.

In FIG. 4, on the planarizing film 110, there is formed a lower electrode 120. The lower electrode 120 is formed of a metal film made, for example, of Al with a high reflectance in order for reflecting upward the light emitted from an organic EL layer 121. On the lower electrode 120, there is formed the organic EL layer 121 for emitting the light. Although depending on the electrode structure, the organic EL layer 121 having the lower electrode 120 used as an anode is composed of a plurality of layers such as a hole injection layer, a hole transportation layer, a light emitting layer, an electron transportation layer, and an electron injection layer stacked on the lower electrode 120 in this order.

On the organic EL layer 121, there is formed an upper electrode 122 as a transparent electrode. Since FIG. 4 shows the top-emission organic EL display, the upper electrode 122 needs to be transparent. As the upper electrode 122, a transparent conductive film such as ITO or AZO is used. Further, an extremely thin metal foil is also used in some cases.

The configuration of the TFT substrate 100 provided with the organic EL layer 121 of the organic EL display is described hereinabove. The organic EL layer 121 is deteriorated in the light emission characteristic by moisture. Therefore, it is necessary to protect the organic EL layer 121 from moisture. Therefore, in order for keeping the organic EL layer 121 airtight from the ambient atmosphere, a transparent sealing substrate 130 is disposed so as to be opposed to the TFT substrate 100 with a slight distance. In some cases, a transparent drying agent is disposed inside the sealing substrate 130.

In the top-emission configuration, the light from the organic EL layer 121 is emitted in a direction of the arrow shown in FIG. 4. The top-emission type has an advantage of disposing the organic EL layer 121 also on the area where the TFT is formed, and making the organic EL layer 121 emit light to contribute to the image formation. Therefore, the top-emission organic EL display is capable of increasing the luminance of the image. It should be noted that the present invention can be applied not only to the top-emission organic EL displays but also to bottom-emission organic EL displays which the light from the organic EL layer 121 is taken out from the TFT substrate 100 side. Both of the top-emission type and the bottom emission type have the same configurations up to the planarizing film 110 shown in FIG. 4.

Although in the embodiment described hereinafter, the liquid crystal display is exemplified for explanations, it can be applied to the organic EL display in a similar manner.

### First Embodiment

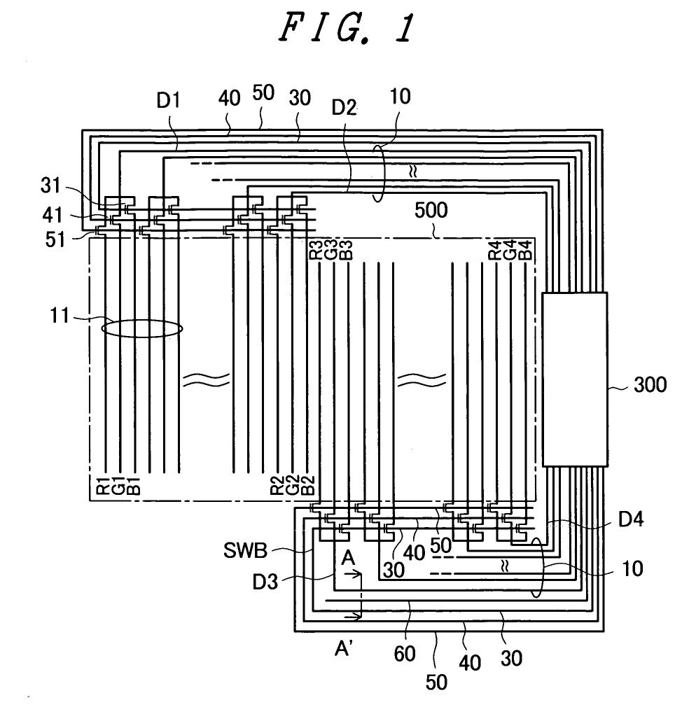

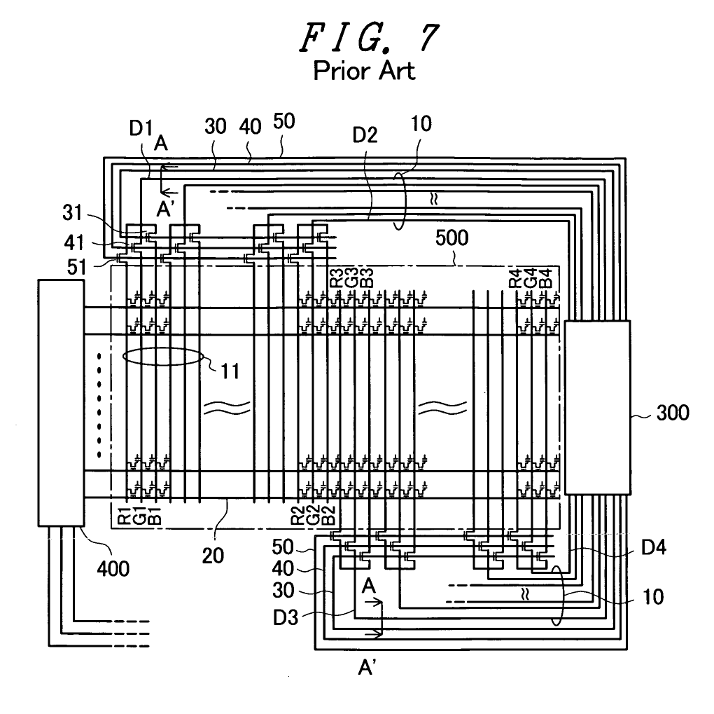

FIG. 1 is a circuit diagram on the TFT substrate 100 side of the liquid crystal display according to a first embodiment of the present invention. In FIG. 1, the drain lines 11 for the RGB video signals extend in a vertical direction and are arranged in a lateral direction in the display area 500. In FIG. 1, for preventing the drawing from becoming complicated, the scan lines 20 are omitted therefrom. In reality, as shown in FIG. 7, the area surrounded by the drain lines 11 and the scan lines 20 becomes a sub-pixel, and in the sub-pixel, there are formed the TFT and the pixel electrode.

On the right of the display area 500 shown in FIG. 1, there is disposed a video signal drive circuit 300. From the video signal drive circuit 300, the driver lines 10 are drawn to the areas disposed above and below the display area 500. The driver lines 10 in the area above the display area 500 have charge of the video signals of the left part of the display area 500, and the driver lines 10 in the area below the display area 500 have charge of the video signals of the right part of the display area 500.

In the areas above and below the display area 500, one driver line 10 branches into three drain lines 11 via three RGB dividing switches. In other words, the three drain lines 11 corresponding to RGB are supplied with the video signals from the driver line 10 in a time-sharing manner. Therefore, in the areas above and below the display area 500, and in the area on the right of the display area 500, the apace required for wiring becomes a third compared to the case in which the drain lines 11 are directly connected to the video signal drive circuit 300. The area of the frame can be reduced accordingly.

In FIG. 1, in order for switching the RGB dividing switches, the RGB switching lines 30, 40, and 50 are drawn from the video signal drive circuit 300. The R switches 51 are controlled with the R switching line 50, the G switches 41 are controlled with the G switching line 40, and the B switches 31 are controlled with the B switching line 30. The R switching line 50, the G switching line 40, and B switching line 30 exist in each of the areas above and below the display area 500.

In FIG. 1, the B switching line 30 and the outermost one of the driver lines 10 are adjacent to each other in each of the areas above and below the display area 500. The outermost driver line D1 and the B switching line 30 are adjacent to each other in the area above the display area 500, and in the area below the display area 500, the outermost driver line D3 and the B switching line 30 are adjacent to each other. On this occasion, interference is caused between the outermost driver line D1 or D3 and the B switching line 30 to modulate the video signal passing through the driver line 10. Moreover, since the both lines run in parallel to each other for a relatively long distance up to the vicinity of the center of the display area 500, the influence thereof is also significant. In contrast, the other driver lines 10 represented by D2 in the area above the display area 500, or the other driver lines 10 represented by D4 in the area below the display area 500 are distant from the B switching line 30, and therefore, free of the influence of the B switching line 30.

Out of the driver lines D1, D3 affected by the B switching lines 30, the drain lines 11, which the driver line D1 in the area above the display area 500 has charge of, are located at the left most end part of the display area 500. In general, the end part of the display area 500 is not very noticeable to human eyes. Therefore, even if the video signals are modulated by the switching signal or the like, a big problem is not caused.

In contrast, the driver line D3 disposed in the area below the display area 500 supplies the drain lines 11 in the center of the display area 500 with the video signals. The driver line D3 is adjacent to the B switching line 30, and is affected by the switching signal for operating the B switch 31. In FIG. 1, on the left of the drain line 11 supplied with the video signal from the driver line D3, there exists the drain line 11 supplied with the video signal from the driver line D2 in the area above the display area 500.

Since the driver line D2 is distant from the B switching line 30, there is no chance to receive the noise caused by the switching signal. On this occasion, since the noise caused by the switching signal from the B switching line 30 is combined only with the drain line 11 supplied with the video signal from the driver line D3, the vertical line noise appears at the center of the display area 500, which causes a significant influence. Therefore, it is necessary to take measures against the influence of the B switching line 30 on the driver line D3 in FIG. 1.

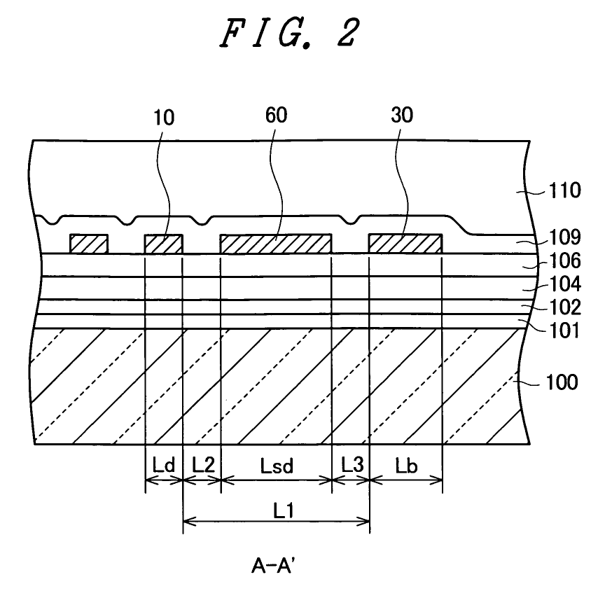

In the present embodiment, as shown in FIG. 1, in the area below the display area 500, a shield line 60 is disposed between the B switching line 30 and the outermost driver line D3 the closest to the B switching line 30, thereby preventing the interference between the B switching line 30 and the driver line D3. FIG. 2 is an A-A′ cross-sectional surface of FIG. 1, and shows a cross-sectional view of the vicinity of the shield line 60.

In FIG. 2, on the TFT substrate 100, there are stacked the first base film 101, the second base film 102, the gate insulating film 104, and the interlayer insulating film 106. On the interlayer insulating film 106, there are disposed the driver line 10, the B switching line 30, and the shield line 60. As shown in FIG. 2, in the present embodiment, the driver line 10, the B switching line 30, and the shield line 60 are formed in the same layer.

The inorganic passivation film 109 is formed so as to cover the driver line 10, the B switching line 30, and the shield line 60, and the planarizing film 110 is formed thereon. In FIG. 2, a line width Ld of the driver line 10 is 3.5 μm, a line width Lb of the B switching line 30 is 10 μm, a line width Lsd of the shield line 60 is 40 μm, a distance L2 between the shield line 60 and the driver line 10 is 5 μm, and a distance L3 between the shield line 60 and the B switching line 30 is 5 μm. Further, a distance L1 between the driver line 10 and the B switching line 30 is 50 μm.

In the arrangement shown in FIG. 2, a coupling capacitance between the driver line 10 and the B switching line 30 becomes about 0.1 pF, namely, the coupling capacitance therebetween dramatically decreases to be about a tenth compared to the conventional configuration without the shield line 60. By adopting the configuration described above, the influence of the B switching line 30 on the driver line D3 can be reduced, and the vertical line can also be prevented from appearing at the center of the display area 500.

In the explanation described above, it is assumed that the interference between the B switching line 30 and the outermost one of the driver lines 10 is the problem. This is because in FIG. 1, the B switching line 30 is disposed the closest to the driver lines 10. However, depending on the arrangement of the RGB switching lines, it is possible that the G switching line 40 or the R switching line 50 is disposed the closest to the driver lines 10. Also in such cases, similarly to the case described above, by disposing the shield line 60 between the G switching line 40 or the R switching line 50 and the outermost driver line 10, it is possible to take a measure against the vertical line at the center of the display area 500.

### Second Embodiment

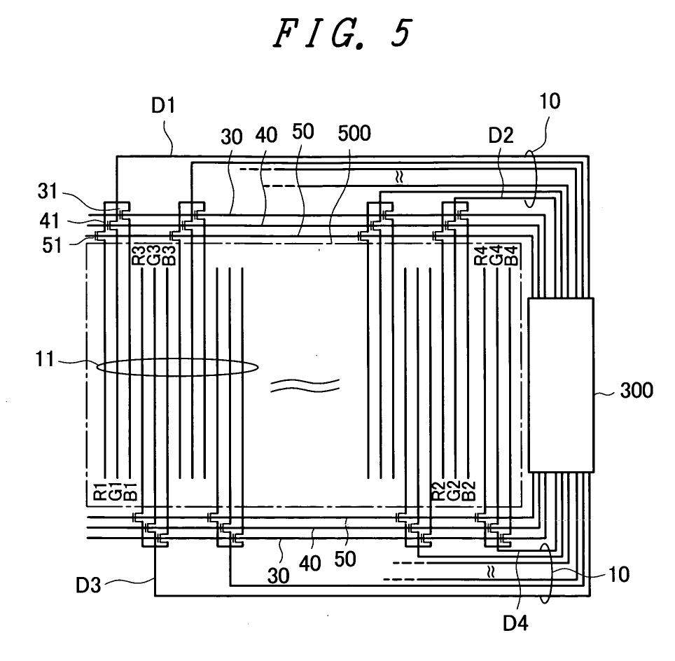

FIG. 5 shows a second embodiment of the present invention. Although FIG. 5 is a circuit diagram of the liquid crystal display panel, scan lines, a scan signal drive circuit, and so on are omitted. In the first embodiment, the display area 500 is equally divided into the left half and the right half, the left half of the display area 500 is supplied with the video signals by the driver lines 10 disposed in the area above the display area 500, and the right half of the display area 500 is supplied with the video signals by the driver lines 10 disposed in the area below the display area 500. Further, against the vertical line noise appears at the center of the display area 500, the measure is taken by disposing the shield line 60 between the B switching line 30 and the outermost one of the driver lines 10.

In the present embodiment, a measure is taken against the vertical line by adopting a different wiring method of the driver lines 10 for supplying the drain lines 11 of the display area 500 with the video signals from that of the first embodiment. In FIG. 5, on the right of the display area 500, there is disposed the video signal drive circuit 300. In the display area 500, there exist the RGB drain lines 11 extending in the vertical direction. Each of the RGB drain lines 11 is supplied with the video signal from one driver line 10 via the respective one of the RGB dividing switches.

The second embodiment is different from the first embodiment in that sets of three drain lines 11 corresponding respectively to RGB are supplied with the video signals alternately from the driver lines 10 in the area above the display area 500 and the driver lines 10 in the area below the display area 500. In FIG. 5, the right most R, G, and B drain lines R4, G4, and B4 in the display area 500 are supplied with the video signals from the driver line D4 disposed in the area below the display area 500. The second right most R, G, and B drain lines R2, G2, and B2 are supplied with the video signals from the driver line D2 disposed in the area above the display area 500.

In FIG. 5, the R switching lines 50, the G switching lines 40, and the B switching lines 30 extending from the video signal drive circuit 300 are disposed inside the driver lines 10 in both of the areas above and below the display area 500. Thus, since the need for folding the R switching lines 50, the G switching lines 40, and the B switching lines 30 is eliminated as shown in FIG. 1, a narrower frame width can be achieved. Further, the distance for which the R switching lines 50, the G switching lines 40, and the B switching lines 30 run in parallel with the driver lines 10 can be shortened.

In FIG. 5, the B switching lines 30 are the closest to the driver lines 10 out of the RGB switching lines. Further, in the area above the display area 500, the driver line D2 is the closest to the B switching line 30, and in the area below the display area 500, the driver line D4 is the closest to the B switching line 30. Therefore, the video signals supplied from D2 or D4 are affected by the switching lines.

As shown in FIG. 5, the distance for which the B switching line 30 runs in parallel with the driver line D4 or D2 is much shorter than the distance for which the driver line D3 and the B switching line 30 run in parallel with each other in FIG. 1. Therefore, even if the video signals are modulated by the switching signal, the influence is weak. Further, the drain lines R4, G4, and B4 supplied with the video signals from the driver line D4 or the drain lines R2, G2, and B2 supplied with the video signals from the driver line D2 are located in the right end of the display area 500, and therefore, even if the video signals are modulated by the switching signal, the influence appearing in the end of the display area 500 is unnoticeable to the observer, and therefore, not significant.

On the other hand, although the drain lines R1, G1, and B1 in the left most part of the display area 500 are supplied with the video signals from the driver line D1 in the area above the display area 500, since the driver line D1 is distant from the B switching line 30, there is no chance that the video signals are affected by the switching signal. Further, although the drain lines R3, G3, and B3 in the left part of the display area 500 are supplied with the video signals from the driver line D3 in the area below the display area 500, since the driver line D3 is distant from the B switching line 30, there is no chance that the video signals are affected by the switching signal.

Although the explanation is presented hereinabove regarding the right end and the left end of the display area 500, since the driver lines 10 and the B switching line 30 are also distant from each other in the center part of the display area 500, there is no chance that the video signals are affected by the switching signal. As described above, according to the present embodiment, since the distance for which the B switching line 30 and the closest driver line D2 or D4 run in parallel with each other can be made shorter, the interference between the switching signal and the video signals can be reduced to the minimum. Further, even if some interference between the switching signal and the video signal remains, the area thereof is the periphery of the display area 500, which is unnoticeable, and therefore, there is no substantial influence.

Also in the present embodiment, it is assumed that the interference between the B switching line 30 and the outermost one of the driver lines 10 is the problem. However, depending on the arrangement of the RGB switching lines, it is possible that the G switching line 40 or the R switching line 50 is disposed the closest to the driver lines 10. However, in such cases, the same advantage can be obtained.

Further, in the present embodiment, it is also possible to add the shield line 60 as explained in the first embodiment. In this case, it is enough for the shield line 60 to be disposed between a set of the R switching line 50, the G switching line 40, and the B switching line 30 and the closest one of the driver lines 10 to the set.

### Third Embodiment

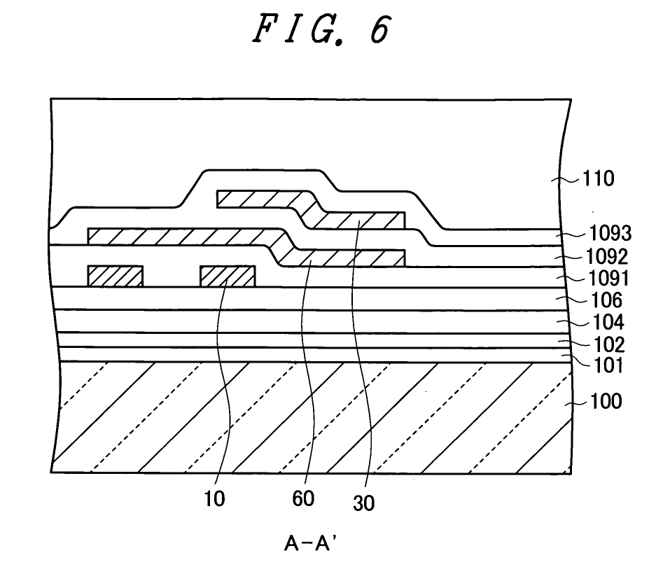

FIG. 6 is a cross-sectional view shows a third embodiment of the present invention. The circuit diagram on the TFT substrate 100 of the liquid crystal display to which the present embodiment is applied is the same as shown in FIG. 1. In FIG. 1, the shield line 60 is disposed between the B switching line 30 and the driver line D3 in order for preventing the interference between the B switching line 30 and the driver line D3 thereby preventing the vertical line at the center of the display area 500. As shown in FIG. 2, the shield line 60 has the width Lsd as large as about 40 μm. Further, it is required to provide spaces L2, L3 on both sides of the shield line 60. Therefore, the frame area becomes large.

FIG. 6 is a cross-sectional view corresponding to the A-A′ cross-sectional surface in FIG. 1 according to the present embodiment. In FIG. 6, on the TFT substrate 100, there are stacked the first base film 101, the second base film 102, the gate insulating film 104, and the interlayer insulating film 106. On the interlayer insulating film 106, there are disposed driver lines 10. The driver lines 10 are formed in the same layer as the drain lines 11. In the present embodiment, in contrast to the first embodiment, the RGB switching lines (the R switching line 50, the G switching line 40, and the B switching line 30) and the shield line 60 are formed in different layers from the drain lines 11.

In FIG. 6, on the driver lines 10, there is formed a first inorganic passivation film 1091 made of SiN. On the first inorganic passivation film 1091, there is formed the shield line 60. The shield line 60 covers at least the outermost one of the driver lines 10, namely the driver line D3 shown in FIG. 1. On the shield line 60, there is formed a second inorganic passivation film 1092 made of SiN. Further, on the second inorganic passivation film 1092, there is formed the B switching line 30.

A third inorganic passivation film 1093 made of SiN is formed so as to cover the B switching line 30, and the planarizing film 110 is formed thereon. It should be noted that since the first and second inorganic passivation films have already existed as the passivation films for protecting the TFT, the third inorganic passivation film 1093 is not necessarily required. However, in some cases, the third inorganic passivation film is required for preventing the B switching line 30 from being oxidized in calcining the planarizing film 110.

As shown in FIG. 6, the B switching line 30 and the driver line 10 overlap with each other in a plan view. Therefore, the planar wiring space can be reduced compared to the case with the first embodiment. In other words, the frame area can be reduced. In FIG. 6, the shield line 60 covers not only the outermost driver line D3 but also the inner driver line 10. This is for preventing the interference between the inner driver line 10 and the B switching line 30.

In the present embodiment, by forming the driver lines 10, the shield line 60, and the RGB switching lines in the different layers, it is possible to dispose the driver lines 10 and the RGB switching lines at the positions overlapping with each other in a plan view. This is because the shield line 60 existing between the driver lines 10 and the RGB switching lines can prevent the interference therebetween.

Incidentally, there is a problem in the present embodiment that since the shield line 60 and the RGB switching lines are formed in different layers, the number of processes increases. However, the present embodiment is an effective measure for making the frame area extremely small and at the same time for preventing the interference between the driver lines 10 and the RGB switching lines.

It should be noted that also in the case with the present embodiment, depending on the arrangement of the RGB switching lines, it is possible that the G switching line 40 or the R switching line 50 is disposed the closest to the driver lines 10. In such cases, it is possible to apply the present invention to the G switching line 40 or the R switching line 50.

Further, in the case in which the shield line is added thereto in the second embodiment, the structure of the present embodiment can also be applied.

Further, the present invention can variously be modified within the technical concept of the present invention. For example, although in the first through third embodiments, examples using the pixels of RGB are described, the present invention can be applied to the pixels of RGBW added with W (white) color. Further, the present invention can also be applied to the pixels with the other colors than RGB, such as cyan, magenta, and yellow. Further, although the explanations are presented exemplifying the case in which the number of branches from the driver line 10 to the drain lines 11 is three, the present invention can be applied to the cases in which the number of branches is equal to or larger than two. Further, it is also possible to use a drive circuit obtained by integrating the scan signal drive circuit 400 and the video signal drive circuit 300 into a single chip.

What is claimed is:

1. A display device comprising:
a display area divided into a first display section and a second display section;
a video signal drive circuit disposed laterally adjacent to the display area and closer to the first display section than to the second display section;
at least two driver lines connected to the video signal drive circuit and adapted to supply the first display section with a plurality of video signals via one of areas above and below the display area, and to supply the second display section with a plurality of video signals via the other of the areas above and below the display area;
an R drain line branched from each of the driver lines via an R switch and adapted to supply red sub-pixels in the display area with one of the video signals;
a G drain line branched from each of the driver lines via a G switch and adapted to supply green sub-pixels in the display area with another of the video signals;
a B drain line branched from each of the driver lines via a B switch and adapted to supply blue sub-pixels in the display area with another of the video signals;
an R switching line adapted to control the R switch;
a G switching line adapted to control the G switch;
a B switching line adapted to control the B switch; and
a shield line disposed between one of the driver lines supplying the R, G, and B drain lines in a boundary section between the first and second display sections with the video signals and either one of the R, G, and B switching lines adjacent to the driver line supplying the R, G, and B drain lines in the boundary section with the video signals.

2. The display device according to claim 1, wherein
the driver line supplying the R, G, and B drain lines in the boundary section between the first and second display sections with the video signals supplies the first display section with the video signals.

3. The display device according to claim 1, wherein
the first and second display sections have the same area.

4. The display device according to claim 1, wherein
the R, G, and B switches are each formed of a TFT.

5. The display device according to claim 1, wherein
the either one of the R, G, and B switching lines adjacent to the driver line supplying the R, G, and B drain lines in the boundary section between the first and second display sections with the video signals is the B switching line.

6. The display device according to claim 1, wherein
the driver lines, the shield line, and the R, G, and B switching lines are formed in the same layer.

7. The display device according to claim 1, wherein
the shield line has a larger width than the widths of the driver lines, and the R, G, and B switching lines.

8. A display device comprising:
a display area;
a video signal drive circuit disposed laterally adjacent to the display area;
a first driver line connected to the video signal drive circuit and disposed in an area above the display area;
a second driver line connected to the video signal drive circuit and disposed in an area below the display area;
a first R drain line branched from the first driver line via a first R switch and adapted to supply red sub-pixels with one of the video signals;
a first G drain line branched from the first driver line via a first G switch and adapted to supply green sub-pixels with another of the video signals;
a first B drain line branched from the first driver line via a first B switch and adapted to supply blue sub-pixels with another of the video signals;
a second R drain line branched from the second driver line via a second R switch and adapted to supply red sub-pixels with one of the video signals;
a second G drain line branched from the second driver line via a second G switch and adapted to supply green sub-pixels with another of the video signals;
a second B drain line branched from the second driver line via a second B switch and adapted to supply blue sub-pixels with another of the video signals;
wherein at least one set of the first R, G, and B drain lines and at least one set of the second R, G, and B drain lines exist alternately in the display area.

9. The display device according to claim 8, further comprising:
an R switching line adapted to control the first and second R switches;
a G switching line adapted to control the first and second G switches; and
a B switching line adapted to control the first and second B switches,
wherein the R, G, and B switching lines are disposed between the first driver line and the display area in the area above the display area, and between the second driver line and the display area in the area below the display area.

10. The display device according to claim 9, further comprising:
a shield line disposed between a set of the R, G, and B switching lines, and at least one of the first and second driver lines the closest to the set of the R, G, and B switching lines.

11. The display device according to claim 8, wherein
the first and second R, G, and B switches are each formed of a TFT.

12. A display device comprising:
a display area divided into a first display section and a second display section;
a video signal drive circuit disposed laterally adjacent to the display area and closer to the first display section than to the second display section;
at least two driver lines connected to the video signal drive circuit and adapted to supply the first display section with a plurality of video signals via one of areas above and below the display area, and to supply the second display section with a plurality of video signals via the other of the areas above and below the display area;
an R drain line branched from each of the driver lines via an R switch and adapted to supply red sub-pixels in the display area with one of the video signals;
a G drain line branched from each of the driver lines via a G switch and adapted to supply green sub-pixels in the display area with another of the video signals;
a B drain line branched from each of the driver lines via a B switch and adapted to supply blue sub-pixels in the display area with another of the video signals;
an R switching line adapted to control the R switch;
a G switching line adapted to control the G switch;
a B switching line adapted to control the B switch; and
a shield line intervening between one of the driver lines supplying the R, G, and B drain lines in a boundary section between the first and second display sections with the video signals and either one of the R, G, and B switching lines adjacent to the driver line supplying the R, G, and B drain lines in the boundary section with the video signals via an insulating film so as to overlap at least one of the driver line supplying the R, G, and B drain lines in the boundary section with the video signals and the either one of the R, G, and B switching lines adjacent to the driver line supplying the R, G, and B drain lines in the boundary section with the video signals.

13. The display device according to claim 12, wherein
the shield line has a larger width than the widths of the driver lines, and the R, G, and B switching lines.

14. The display device according to claim 1, wherein
the display device is a liquid crystal display.

15. The display device according to claim 1, wherein
the display device is an organic EL display.
